(19) United States
(12) Patent Application Publication
(10) Pub. No.: US 2021/0066159 A1
(43) Pub. Date: Mar. 4, 2021

(54) HEAT DISSIPATION BOARD AND ELECTRONIC APPARATUS

(71) Applicant: KYOCERA Corporation, Kyoto-shi, Kyoto (JP)

(72) Inventors: Shinya TOMIDA, Yasu-city (JP); Hisaki MASUDA, Hikone-city (JP); Toshiharu KOMORI, Otsu-city (JP); Norimasa UEDA, Higashiomi-city (JP)

(73) Assignee: KYOCERA Corporation, Kyoto-shi, Kyoto (JP)

(21) Appl. No.: 17/050,643

(22) PCT Filed: Apr. 23, 2019
(86) PCT No.: PCT/JP2019/017266

§ 371 Date: Oct. 26, 2020

(30) Foreign Application Priority Data
Apr. 26, 2018 (JP) 2018-085130

(51) Int. Cl. H01L 23/373

(52) U.S. Cl. CPC H01L 23/3735

(57) ABSTRACT

A heat dissipation board includes a substrate, first, second, and third portions, and a bond. The substrate has a through-hole and includes a metal material. The first portion is located in the through-hole. The first portion has a higher thermal conductivity than the substrate and includes a metal material. The second portion is located on an upper surface of the substrate. The second portion has a higher thermal conductivity than the substrate and includes a metal material. The third portion is located on a lower surface of the substrate. The third portion has a higher thermal conductivity than the substrate and includes a metal material. The bond is between the substrate and the second portion, and between the substrate and the third portion. The first portion is at least partially continuous with the second portion and with the third portion through the bond or the bonding layer.

### FIELD

The present invention relates to a heat dissipation board on which a semiconductor device is mountable, and an electronic apparatus including the heat dissipation board.

### BACKGROUND

A known semiconductor package contains an electronic component, such as a semiconductor device, that operates with high-frequency signals. Such a semiconductor device generates heat during operation. To dissipate such heat outside, a known heat dissipation board on which such a semiconductor device is mountable improves heat dissipation by partially incorporating a metal body containing a material with a higher thermal conductivity (refer to Japanese Unexamined Patent Application Publication No. 2018-18976).

The method described in Japanese Unexamined Patent Application Publication No. 2018-18976 includes partially melting and thus bonding the metal body for forming the heat dissipation board. This includes reducing the difference in thermal expansion between the heat dissipation board and the electronic component to be mounted. However, the heat dissipation board described in Japanese Unexamined Patent Application Publication No. 2018-18976 may deform under heat for the melting.

### BRIEF SUMMARY

A heat dissipation board according to one embodiment of the present invention includes a substrate, a first portion, a second portion, a third portion, and a bond. The substrate has at least one through-hole and includes a metal material. The first portion is located in the through-hole. The first portion has a higher thermal conductivity than the substrate and includes a metal material. The second portion is located on an upper surface of the substrate. The second portion has a higher thermal conductivity than the substrate and includes a metal material. The third portion is located on a lower surface of the substrate. The third portion has a higher thermal conductivity than the substrate and includes a metal material. The bond is located between the substrate and the second portion, and between the substrate and the third portion. The first portion is at least partially continuous with the second portion and with the third portion through the bond.

A heat dissipation board according to another embodiment of the present invention includes a substrate, a first portion, a second portion, and a third portion. The substrate has at least one through-hole and includes a metal material. The first portion is located in the through-hole. The first portion has a higher thermal conductivity than the substrate and includes a metal material. The second portion is located on an upper surface of the substrate. The second portion has a higher thermal conductivity than the substrate and includes a metal material. The third portion is located on a lower surface of the substrate. The third portion has a higher thermal conductivity than the substrate and includes a metal material. The first portion is at least partially continuous with the second portion and with the third portion. A bonding layer is located between the substrate and the second portion, and between the substrate and the third portion.

### BRIEF DESCRIPTION OF DRAWINGS

FIG. 1 is a partial cross-sectional view of a heat dissipation board according to an embodiment of the present invention.

FIG. 2 is a cross-sectional view of the heat dissipation board according to the embodiment of the present invention.

FIG. 3 is an exploded plan view of the heat dissipation board according to the embodiment of the present invention.

FIG. 4 is an exploded perspective view of the heat dissipation board according to the embodiment of the present invention.

FIG. 5 is a cross-sectional view of an electronic apparatus according to an embodiment of the present invention.

FIG. 6 is a side view of the heat dissipation board according to the embodiment of the present invention.

FIG. 7 is a partial cross-sectional view of a heat dissipation board according to another embodiment of the present invention.

FIG. 8 is an exploded perspective view of a heat dissipation board according to another embodiment of the present invention.

FIG. 9 is a perspective view of an electronic apparatus according to an embodiment of the present invention.

FIG. 10 is a perspective view of the electronic apparatus according to the embodiment of the present invention.

### DETAILED DESCRIPTION

A semiconductor package according to one or more embodiments and an electronic apparatus including the semiconductor package will now be described in detail with reference to the drawings.

### Heat Dissipation Board Structure

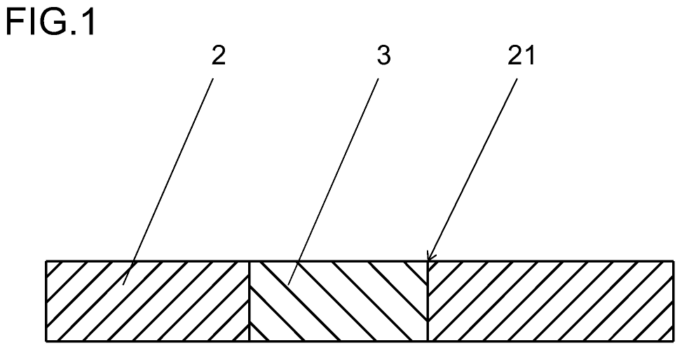

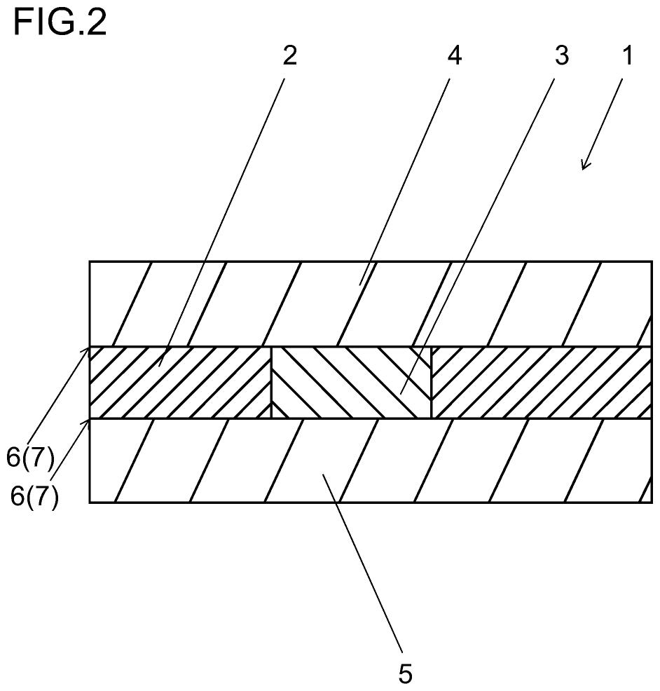

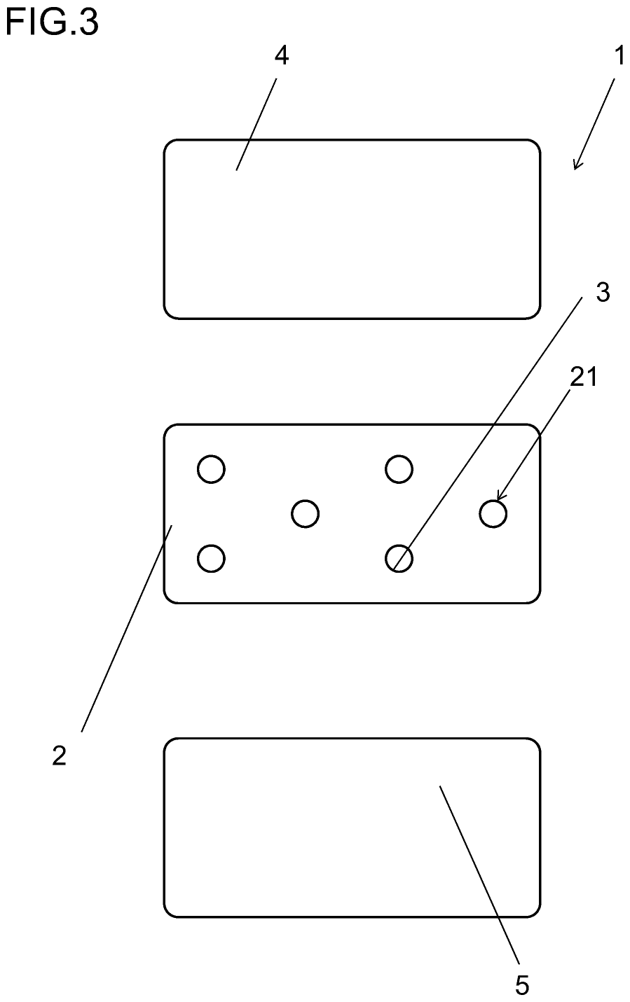

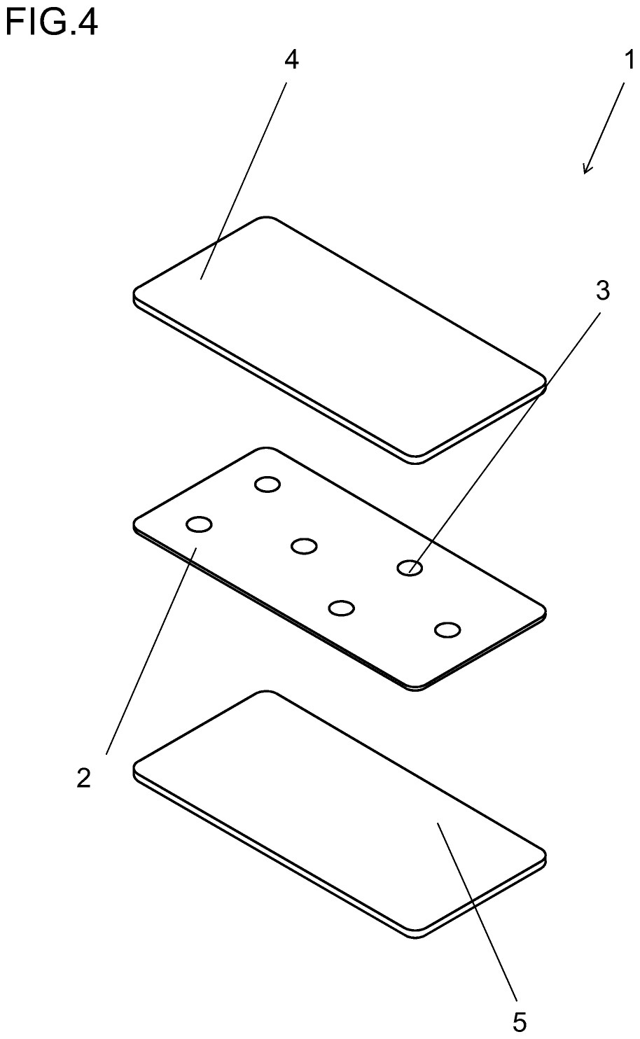

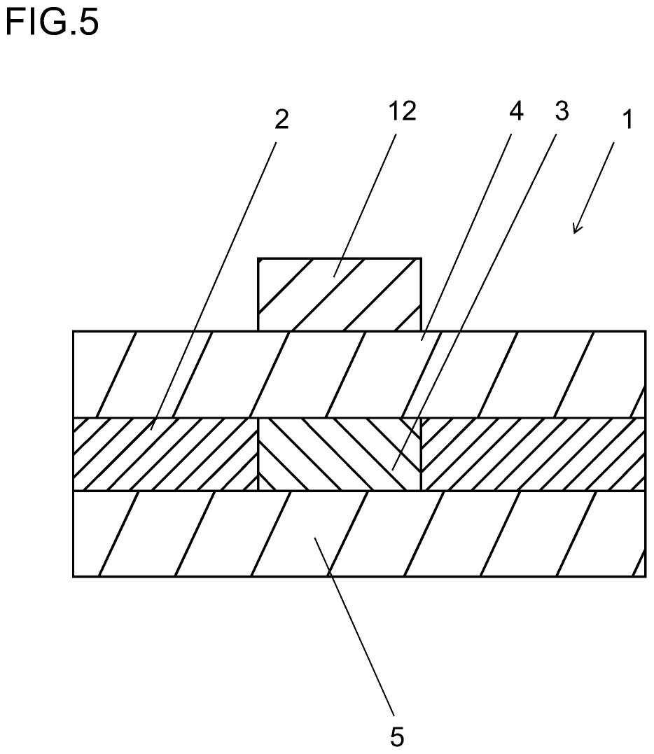

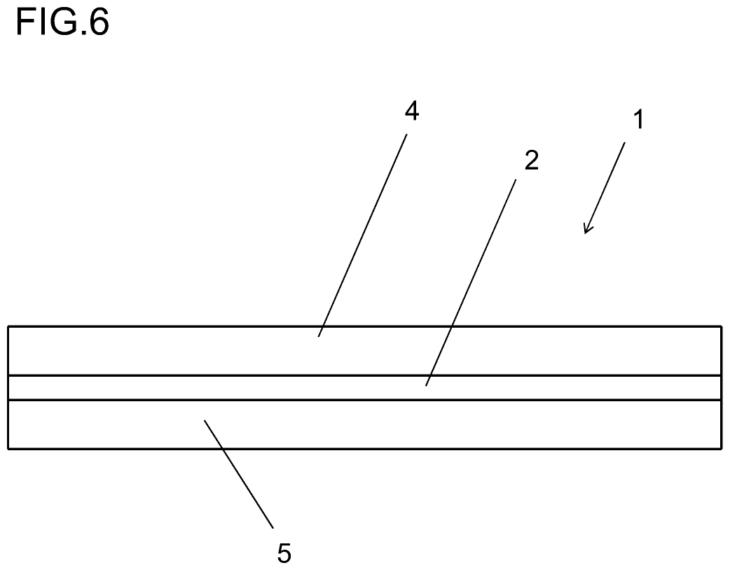

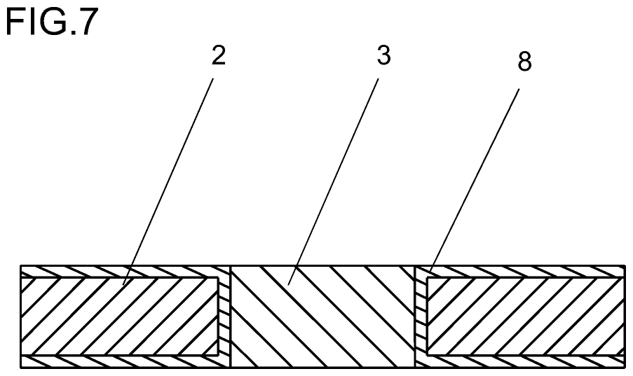

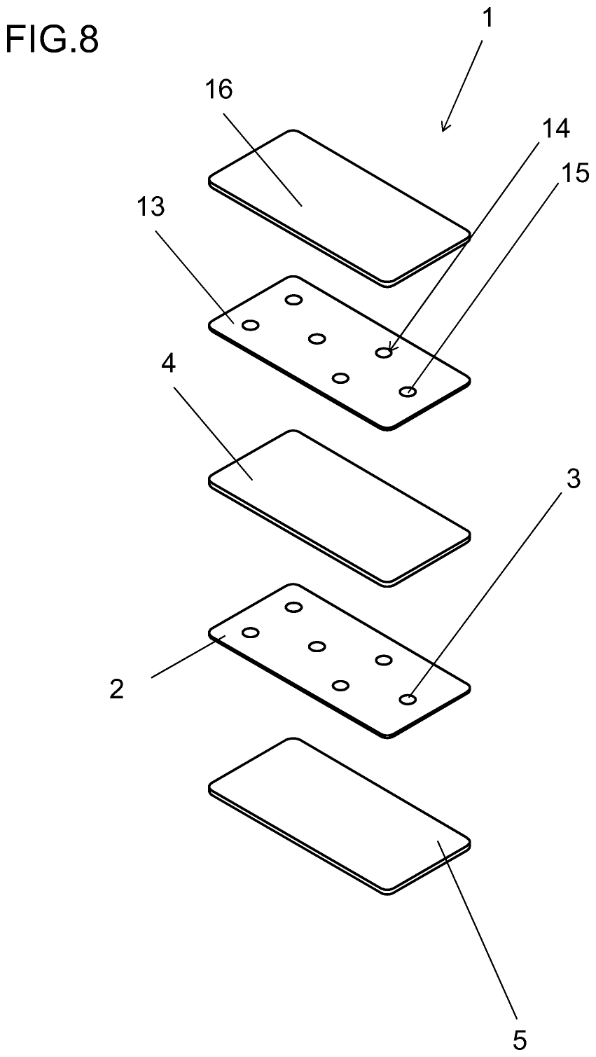

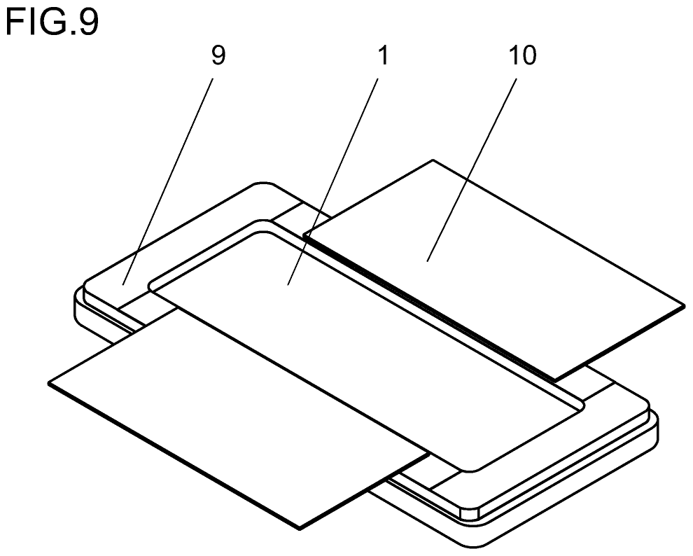

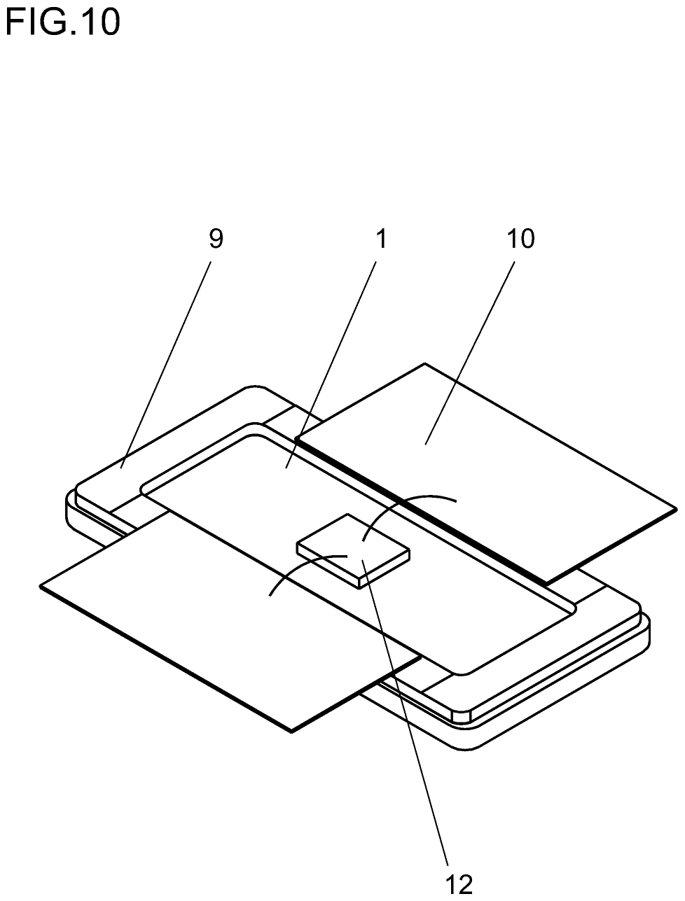

FIG. 1 is a partial cross-sectional view of a heat dissipation board according to an embodiment of the present invention. FIG. 2 is a cross-sectional view of the heat dissipation board according to the embodiment of the present invention. FIG. 3 is an exploded plan view of the heat dissipation board according to the embodiment of the present invention. FIG. 4 is an exploded perspective view of the heat dissipation board according to the embodiment of the present invention. FIG. 5 is a cross-sectional view of an electronic apparatus according to an embodiment of the present invention. FIG. 6 is a side view of the heat dissipation board according to the embodiment of the present invention. FIG. 7 is a partial cross-sectional view of a heat dissipation board according to another embodiment of the present invention. FIG. 8 is an exploded perspective view of a heat dissipation board according to another embodiment of the present invention. FIG. 9 is a perspective view of an electronic apparatus according to an embodiment of the present invention. FIG. 10 is a perspective view of the electronic apparatus according to the embodiment of the present invention. In each of these figures, a heat dissipation board 1 according to one or more embodiments of the present invention includes a substrate 2, at least one first portion 3, a second portion 4, and a third portion 5. The heat dissipation board 1 according to an embodiment of the present invention includes bonds 6 or bonding layers 7. The structure may include a frame 9 and input-output terminals 10. The substrate 2 has at least one through-hole 21 each receiving a first portion 3.

As shown in FIG. 3, the substrate 2 in an embodiment of the present invention is, for example, rectangular. The substrate 2 is formed from, for example, a metal material. Examples of the metal material include molybdenum. In this case, the substrate 2 has a thermal expansion coefficient of about 5×10⁻⁶/K. The substrate 2 may be formed from iron, nickel, chromium, cobalt, tungsten, or an alloy of any of these metals. The metal member for the substrate 2 may be prepared by processing (e.g., rolling or punching) an ingot formed from such a metal material.

The substrate 2 has the through-hole 21 aligning with an area in which an electronic component (described later) is mountable. The substrate 2 is rectangular and has dimensions of, for example, 5×5 mm to 40×40 mm. The through-hole 21 is, for example, circular in a plan view. The through-hole 21 has a diameter of 0.5 to 5 mm in a plan view. The through-hole 21 has a thickness of 0.1 to 3 mm. The through-hole 21 may use 1 to 20% of the area of the substrate 2 in a plan view. The through-hole 21 using 2% or more of the area improves heat dissipation. The through-hole 21 using 20% or less of the area reduces deformation of the substrate 2.

As shown in FIG. 1, the first portion 3 is received in the through-hole 21 in the substrate 2. To be received in the through-hole 21, the first portion 3 has an outer dimension at least smaller than the through-hole 21. The first portion 3 being smaller than the through-hole 21 includes having substantially the same dimension as the through-hole 21, and being smaller than the through-hole 21 with a clearance to be filled with a bond. For example, when the first portion 3 is circular in a plan view, the first portion 3 has a diameter of 0.5 to 5 mm and a thickness of 0.1 to 3 mm. The first portion 3 has its lower surface flush with the lower surface of the substrate 2. In some embodiments, the first portion 3 may at least protrude from the lower surface of the substrate 2.

The first portion 3 may either contain or be formed from, for example, copper. In this case, the substrate 2 has a thermal expansion coefficient of about 16×10⁻⁶/K. The first portion 3 may be formed from any metal material that has high heat dissipation, such as copper. For example, the first portion 3 may be formed from an alloy of copper and tungsten or molybdenum. In this case, the first portion 3 has a thermal expansion coefficient of, for example, 10×10⁻⁶ to 20×10⁻⁶/K. The first portion 3 aligns with a mount area for an electronic component 12 to cause heat from the electronic component 12 on the mount area to transfer through the second portion to the first portion 3 and then out of the heat dissipation board 1.

Multiple through-holes 21 and multiple first portions 3 may be located under the electronic component 12. Such multiple through-holes 21 and multiple first portions 3 may be designed and sized in accordance with the size of the electronic component. The substrate 2 can be processed easily and thus with higher productivity.

As shown in FIG. 2, the second portion 4 is located on the upper surfaces of the substrate 2 and the first portion 3. For example, the second portion 4 has dimensions of 5×5 mm to 40×40 mm in a plan view, which may be the same as those of the substrate 2. The second portion 4 has a thickness of 0.1 to 3 mm.

The second portion 4 may either contain or be formed from copper. In this case, the substrate 2 has a thermal expansion coefficient of about 16×10⁻⁶/K. The second portion 4 may be formed from any metal material that has high heat dissipation, such as copper. For example, the second portion 4 may be formed from an alloy of copper and tungsten or molybdenum. In this case, the second portion 4 has a thermal expansion coefficient of, for example, 10×10⁻⁶ to 20×10⁻⁶/K. The second portion 4 aligns with the mount area to cause heat from the electronic component 12 on the mount area to transfer through the second portion 4 to the first portion 3.

As shown in FIG. 2, the third portion 5 is located on the lower surfaces of the substrate 2 and the first portion 3. For example, the third portion 5 has dimensions of 5×5 mm to 40×40 mm in a plan view, which may be the same as those of the substrate 2. The third portion 5 has a thickness of 0.1 to 3 mm.

The third portion 5 may either contain or be formed from copper. In this case, the substrate 2 has a thermal expansion coefficient of about 16×10⁻⁶/K. The third portion 5 may be formed from any metal material that has high heat dissipation, such as copper. For example, the third portion 5 may be formed from an alloy of copper and tungsten or molybdenum. In this case, the third portion 5 has a thermal expansion coefficient of, for example, 10×10⁻⁶ to 20×10⁻⁶/K. The third portion 5 aligns with the mount area to cause heat from the electronic component 12 on the mount area to transfer through the second portion 4 and the first portion 3 to the third portion 5. The third portion 5 may have a thickness equal to or smaller than the thickness of the second portion 4.

The first portion 3, the second portion 4, and the third portion 5 may be formed from the same material. In this case, the heat dissipation board 1 has higher productivity and is economical. With the second portion 4 and the third portion 5 having the same thermal expansion coefficient, the heat dissipation board 1 is less likely to warp under heat. A substrate formed from copper alone may have higher thermal stress with an electronic component. A substrate formed from a material having a low thermal expansion coefficient to reduce such thermal stress may not dissipate heat from an electronic component, possibly causing failures. This structure reduces the likelihood of causing failures in an electronic component due to the use of materials having different thermal expansion coefficients described above.

As shown in FIG. 5, the mount area of the second portion 4 for receiving the electronic component 12 vertically aligns with and joined to the first and third portions each having a higher thermal conductivity than the substrate 2. This structure allows heat from the electronic component 12 to be efficiently dissipated outside without being blocked by the substrate 2, thus improving the reliability of the electronic component.

A bonding layer 7 may be located between the second portion 4 and the substrate 2 including the first portion 3, and between the third portion 5 and the substrate 2 including the first portion 3. The bonding layer 7 is an alloy layer that results from a chemical reaction during thermocompression bonding. The alloy layer allows tighter bonding between the substrate 2, the first portion 3, and the second portion 4 to improve the durability of the heat dissipation board 1, and also improves vertical heat dissipation through the second portion, the first portion, and the third portion.

A bond 6 may be located between the second portion 4 and the substrate 2 including the first portion 3, and between the third portion 5 and the substrate 2 including the first portion 3. The bond is, for example, a brazing material such as silver solder. The brazing material bonds the second portion 4 to the substrate 2 including the first portion 3, and bonds the third portion 5 to the substrate 2 including the first portion 3. As shown in FIG. 7, the substrate 2 may include a plating layer 8 on the surface of the substrate 2 including the inner surface of the through-hole 21. The plating layer 8 is, for example, a layer of nickel. The plating layer can tightly adhere to the bond, thus improving the durability of the heat dissipation board 1.

The first portion 3, the second portion 4, and the third portion 5 may be at least partially continuous with one another through the bond 6 or the bonding layer 7, forming a heat path. The first portion 3, the second portion 4, and the third portion 5 may be entirely continuous with one another through the bond 6 or the bonding layer 7. This allows more heat dissipation than these portions being partially continuous. A fourth portion 15 and a fifth portion 16 (described later) may also be at least partially continuous with each other through the bond 6 or the bonding layer 7. Further, the fourth portion 15 and the fifth portion 16 may be at least partially continuous with the first portion 3, the second portion 4, and the third portion 5, forming a heat path. The fourth portion 15 and the fifth portion 16 may be entirely continuous with each other through the bond 6 or the bonding layer 7. The fourth portion 15 and the fifth portion 16 may also be entirely continuous with the first portion 3, the second portion 4, and the third portion 5 through the bond 6 or the bonding layer 7. This allows more heat dissipation than these portions being partially continuous.

A heat dissipation board 1 according to another embodiment of the present invention may further include a second substrate 13, the fourth portion 15, and the fifth portion 16 on the upper surface of the second portion 4 as shown in FIG. 8, or on the lower surface of the third portion. In other words, the heat dissipation board may be five-layered.

The second substrate 13 is, for example, rectangular. The second substrate 13 is formed from, for example, a metal material. Examples of the metal material include molybdenum. In this case, the second substrate 13 has a thermal expansion coefficient of about 5×10⁻⁶/K. The second substrate 13 may be formed from iron, nickel, chromium, cobalt, tungsten, or an alloy of any of these metals. The metal member for the second substrate 13 may be prepared by processing (e.g., rolling or punching) an ingot formed from such a metal material. In other words, the second substrate 13 may be similar to the substrate 2 in shape and material.

The second substrate 13 has at least one second through-hole 14 aligning with the area in which the electronic component is mountable. The second through-hole 14 is, for example, circular in a plan view. The second through-hole 14 has a diameter of 0.5 to 5 mm in a plan view. The second through-hole 14 has a thickness of 0.1 to 3 mm.

The fourth portion 15 is received in the second through-hole 14 in the second substrate 13. To be received in the through-hole 14, the fourth portion 15 has an outer dimension at least smaller than the second through-hole 14. The fourth portion 15 being smaller than the second through-hole 14 includes having substantially the same dimension as the second through-hole 14, and being smaller than the second through-hole 14 with a clearance to be filled with a bond. For example, when the fourth portion 15 is circular in a plan view, the fourth portion 15 has a diameter of 0.5 to 5 mm and a thickness of 0.1 to 3 mm. The fourth portion 15 has its lower surface flush with the lower surface of the second substrate 13. In some embodiments, the fourth portion 15 may at least protrude from the lower surface of the second substrate 13.

The fourth portion 15 may either contain or be formed from, for example, copper. In this case, the substrate 2 has a thermal expansion coefficient of about 16×10⁻⁶/K. The fourth portion 15 may be formed from any metal material that has high heat dissipation, such as copper. For example, the fourth portion 15 may be formed from an alloy of copper and tungsten or molybdenum. The fourth portion 15 has a thermal expansion coefficient of, for example, 10×10⁻⁶ to 20×10⁻⁶/K. In other words, the fourth portion 15 may be similar to the first portion 3 in shape and material.

The fifth portion 16 is located on the upper or lower surface of the second substrate 13. For example, the fifth portion 16 has dimensions of 5×5 mm to 40×40 mm in a plan view, which may be the same as those of the substrate 2. The fifth portion 16 has a thickness of 0.5 to 3 mm. When the fifth portion is located on the upper surface of the second substrate 13, the electronic component 12 is mounted on the upper surface of the fifth portion.

The fifth portion 16 may either contain or be formed from copper. In this case, the substrate 2 has a thermal expansion coefficient of about 16×10⁻⁶/K. The fifth portion 16 may be formed from any metal material that has high heat dissipation, such as copper. For example, the fifth portion 16 may be formed from an alloy of copper and tungsten or molybdenum. The fifth portion 16 has a thermal expansion coefficient of, for example, 10×10⁻⁶ to 20×10⁻⁶/K. In other words, the fifth portion 16 may be similar to the second portion 4 or the third portion 5 in shape and material.

The heat dissipation board 1 additionally including the second substrate 13 and the fourth portion 15 and the fifth portion 16 has better durability. The heat dissipation board 1 having the mount area for receiving the electronic component 12 vertically aligning with and joined to the second portion, the first portion, the third portion, the fourth portion, and the fifth portion each having a higher thermal conductivity allows heat from the electronic component 12 to be efficiently dissipated outside without being blocked by the substrate 2 or the second substrate 13.

In some embodiments, the heat dissipation board may include seven, nine, or more layers including second substrates, fourth portions, and fifth portions that are stacked alternately. The heat dissipation board including a larger number of layers has better durability.

As shown in FIG. 9, an electronic apparatus 20 according to an embodiment of the present invention may include the frame 9 on the upper surface of the heat dissipation board 1. The input-output terminals 10 may be joined and fastened to the frame 9. The first portion 3 is, for example, circular and is located without aligning with the frame 9. The input-output terminals 10 are on the frame 9 along the long side of the heat dissipation board 1. The first portion 3 and the frame 9 without aligning with each other reduce stress caused by the difference in thermal expansion coefficient between the heat dissipation board 1, the frame 9, and the input-output terminals 10. The heat dissipation board 1 thus reduces cracks and breakage in the frame 9, reducing defects in the electronic apparatus 20.

As shown in FIGS. 9 and 10, the electronic apparatus 20 according to the embodiment of the present invention includes the heat dissipation board 1, the frame 9, the input-output terminals 10, and the electronic component 12. The frame 9 surrounds the mount area on the heat dissipation board 1 and is joined to the upper surface of the heat dissipation board 1. The frame 9 has rectangular outer and inner edges in a plan view, and has four side walls. The frame 9 is joined to the upper surface of the heat dissipation board 1 with a bond, such as silver solder.

In a plan view, the frame 9 has an outer edge dimension of, for example, 5×5 mm to 40×40 mm, and an inner edge dimension of 4×4 mm to 35×35 mm. The frame 9 has a thickness, or a width between the outer edge and the inner edge of, for example, 1 to 5 mm. The frame 9 has a height of 1 to 10 mm.

The frame 9 may be formed from, for example, a ceramic material. Examples of the ceramic material include sintered aluminum oxide and sintered aluminum nitride. The frame 9 may also be formed from a resin material, such as an epoxy resin. The frame 9 may be formed from a metal material. Examples of the metal material include iron, copper, nickel, chromium, cobalt, molybdenum, tungsten, and an alloy of any of these metal materials.

As shown in FIG. 9, the input-output terminals 10 may be joined to the frame 9. The input-output terminals may be joined to the upper surface of the frame 9 with a bond, such as gold-tin solder or a resin bond. The input-output terminals 10 are electrically connected to the electronic component 12 mounted on the mount area with, for example, bonding wires, and electrically connected to, for example, an external mounting board, a circuit board, and a power source. The input-output terminals 10 are formed from, for example, an alloy of iron, nickel, and cobalt, or an alloy of iron and nickel.

As shown in FIG. 9, the electronic apparatus 20 according to the embodiment of the present invention may include the first portion 3 having an edge not aligning with the frame 9 in a plan view. The first portion 3 having the edge not aligning with the frame 9 reduces stress at the joint between the substrate 2 and the frame 9 near the edge of the first portion 3 during the manufacture of the heat dissipation board 1 and during the operation of the electronic apparatus 20. More specifically, the joint between the substrate 2 and the frame 9 does not align with the joint between the substrate 2 and the first portion 3 in a plan view of the heat dissipation board 1. This reduces concentration of stress at the joint between the substrate 2 and the frame 9 caused by the difference in thermal expansion coefficient between the substrate 2, the first portion 3, and the frame 9. Thus, the heat dissipation board 1 reduces cracks and breakage at the joint between the substrate 2 and the end face of the first portion 3.

In an electronic apparatus 20 according to another embodiment of the present invention, each input-output terminal 10 may be received in and fastened at a cutout in a side surface of the frame 9 at its center in a plan view. The input-output terminals 10 are, for example, lead terminals formed from a metal material and have a lower thermal expansion coefficient than a thermally conductive metal used for the first portion 3. When the heat dissipation board 1, the frame 9, and the input-output terminals 10 are joined together, the difference in thermal expansion coefficient between these components may produce thermal stress, causing a load on the frame 9. The load on the frame 9 caused by thermal stress can be reduced by reducing the thermal expansion of at least the heat dissipation board 1.

In the electronic apparatus 20 according to the embodiment of the present invention, the first portion 3 may have an edge not aligning with the frame 9 in a plan view, as described above. However, in an electronic apparatus 20 according to another embodiment of the present invention, the first portion 3 may have an edge aligning with the frame 9 in a plan view. The first portion 3 aligning with the frame 9 allows heat from the electronic component 12 to escape outside through the frame 9, as well as through the substrate 2 and an external mounting board.

In a heat dissipation board 1 according to another embodiment of the present invention, the first portion 3 and the through-hole 21 may have curved edges to protrude outward in a plan view. The first portion 3 having the curved edge reduces thermal stress at the joint between the substrate 2 and the edge of the first portion 3 during the manufacture of the heat dissipation board 1 and during the operation of the electronic apparatus 20. The curved edge also reduces local thermal stress.

The electronic component 12 in operation generates heat, causing thermal expansion of the first portion 3 and the substrate 2. When the first portion 3 and the substrate 2 undergo thermal expansion, the first portion 3 having a higher thermal expansion coefficient than the substrate 2 may come in contact with the inner surface of the through-hole 21 in the substrate 2. The first portion 3 and the through-hole 21 with the curved edges have less cracks at the edges.

Thus, the heat dissipation board 1 according to the other embodiment of the present invention reduces cracks and breakage at the joint between the substrate 2 and the end face of the first portion 3. In other words, the heat dissipation board 1 reduces cracks in the first portion 3 and the substrate 2, as well as improving heat dissipation and reducing warpage of the substrate 2.

### Method for Manufacturing Heat Dissipation Board

A substrate 2 formed from, for example, a metal material, such as molybdenum, is prepared. A rectangular through-hole 21 is formed in a center portion of the substrate 2 to have its long side parallel to the long side of a first portion 3 in a cross-sectional view. The first portion 3 is then placed in the through-hole 21. The inner periphery of the through-hole 21 and the side surface of the first portion 3 facing the inner periphery are then joined together by brazing or under vertically applied pressure.

The first portion 3 is formed from, for example, a metal material, such as copper. The first portion 3 is placed in the through-hole 21, leaving a clearance between the side surface of the first portion 3 and the inner periphery of the through-hole 21 to receive a bond such as a brazing material to join the first portion 3 to the through-hole 21.

A second portion 4 and a third portion 5 are prepared. For example, the second portion 4 and the third portion 5 formed from copper may each be shaped into a predetermined dimension by punching with a die or cutting. The substrate 2 with the first portion 3 is then placed between the second portion 4 and the third portion 5. The second portion 4 and the substrate 2 are joined together, and the substrate 2 and the third portion 5 are joined together, through thermocompression bonding or with a bond such as a brazing material.

When the frame 9 is formed from, for example, sintered aluminum oxide, an appropriate amount of a sintering aid, such as magnesia, silica, or calcia, is added to an alumina powder. A solvent is added to the alumina powder, and the mixture is thoroughly kneaded and defoamed to prepare slurry. Using the slurry, a rolled ceramic green sheet is formed with, for example, a doctor blade method, and cut into an appropriate size. Signal lines such as wiring patterns, to which the respective input-output terminals 10 are to be connected and fastened, are screen-printed on the ceramic green sheet prepared by the cutting. The ceramic green sheet is then fired in a reducing atmosphere at about 1600° C. Multiple ceramic green sheets may be stacked on one another before the firing process. The resulting frame 9, which has the input-output terminals 10 joined to its upper surface with, for example, a brazing material, is joined to the upper surface of the heat dissipation board 1 with, for example, gold-tin solder to surround the mount area.

When the substrate 2 and the second substrate 13 are formed from, for example, a ceramic material, a material similar to that of the frame 9 may be used. The substrate 2 and the second substrate 13 formed from sintered aluminum oxide may contain magnesia, silica, or calcia. An appropriate amount of a sintering aid is added to an alumina powder. A solvent is added to the alumina powder, and the mixture is thoroughly kneaded and defoamed to prepare slurry. Using the slurry, a rolled ceramic green sheet is formed with, for example, a doctor blade method, and cut into an appropriate size. The ceramic green sheet that has been formed by cutting is then fired in a reducing atmosphere at about 1600° C. Multiple ceramic green sheets may be stacked on one another before the firing process.

The heat dissipation board 1 according to the embodiments of the present invention can be manufactured in the manner described above. The manufacturing steps are not limited to the order described above.

### Electronic Apparatus Structure

The electronic apparatus 20 according to the embodiment of the present invention will now be described in detail with reference to the drawings. FIGS. 9 and 10 are perspective views of the electronic apparatus 20 according to the embodiment of the present invention. As shown in FIGS. 9 and 10, the electronic apparatus 20 according to the embodiment of the present invention includes the heat dissipation board 1, the frame 9, and the input-output terminals 10 described in the above embodiments, and the electronic component 12 mounted on the mount area on the heat dissipation board 1.

The electronic apparatus 20 according to the embodiment of the present invention includes the electronic component 12 mounted on the mount area on the heat dissipation board 1. The electronic component 12 is electrically connected to signal lines of the input-output terminals 10 with, for example, bonding wires. The electronic component 12 can provide intended output by receiving input of external signals through, for example, the signal lines.

Examples of the electronic component 12 include an integrated circuit (IC), a large-scale integration (LSI), and a semiconductor device for a power device. The frame 9 has an upper surface covered with, for example, a lid. The electronic component 12 is sealed in the space defined by the heat dissipation board 1, the frame 9, and the lid. The sealing reduces the deterioration of the electronic component 12 caused by external factors such as humidity.

The lid may be formed from, for example, a metal material, such as iron, copper, nickel, chromium, cobalt, or tungsten, or an alloy of any of these metals. The frame 9 and the lid can be joined together by, for example, seam welding. The frame 9 and the lid may be joined together with, for example, gold-tin solder.

Although the heat dissipation board 1 and the electronic apparatus 20 including the heat dissipation board 1 according to the embodiments are described above, the present invention is not limited to these embodiments. The embodiments may be modified or combined variously without departing from the spirit and scope of the present invention.

### REFERENCE SIGNS LIST

1 heat dissipation board
2 substrate
21 through-hole
3 first portion
4 second portion
5 third portion
6 bond
7 bonding layer
8 plating layer
9 frame
10 input-output terminal
12 electronic component
13 second substrate
14 second through-hole
15 fourth portion
16 fifth portion
20 electronic apparatus

1. A heat dissipation board, comprising:
a substrate having at least one through-hole, the substrate comprising a metal material;
a first portion in the at least one through-hole, the first portion having a higher thermal conductivity than the substrate and comprising a metal material;
a second portion on an upper surface of the substrate, the second portion having a higher thermal conductivity than the substrate and comprising a metal material;
a third portion on a lower surface of the substrate, the third portion having a higher thermal conductivity than the substrate and comprising a metal material; and
a bond between the substrate and the second portion, and between the substrate and the third portion,
wherein the first portion is at least partially continuous with the second portion and with the third portion through the bond.

2. A heat dissipation board, comprising:
a substrate having at least one through-hole, the substrate comprising a metal material;
a first portion in the at least one through-hole, the first portion having a higher thermal conductivity than the substrate and comprising a metal material;
a second portion on an upper surface of the substrate, the second portion having a higher thermal conductivity than the substrate and comprising a metal material; and
a third portion on a lower surface of the substrate, the third portion having a higher thermal conductivity than the substrate and comprising a metal material,
wherein the first portion is at least partially continuous with the second portion and with the third portion, and a bonding layer is between the substrate and the second portion, and between the substrate and the third portion.

3. The heat dissipation board according to claim 1, wherein
the substrate comprises molybdenum, and
the first portion, the second portion, and the third portion comprise copper.

4. The heat dissipation board according to claim 1, further comprising:
a plating layer on a surface of the substrate and on an inner surface of the at least one through-hole.

5. The heat dissipation board according to claim 1, wherein
the at least one through-hole is circular in a plan view.

6. The heat dissipation board according to claim 1, wherein
the first portion, the second portion, and the third portion each comprise the same material.

7. The heat dissipation board according to claim 1, further comprising:
a second substrate having at least one second through-hole, the second substrate being on an upper surface of the second portion or on a lower surface of the third portion, the second substrate comprising a metal material;
a fourth portion in the at least one second through-hole, the fourth portion having a higher thermal conductivity than the second substrate and comprising a metal material; and
a fifth portion having a higher thermal conductivity than the second substrate and comprising a metal material, the fifth portion being on an upper surface or a lower surface of the second substrate.

8. An electronic apparatus, comprising:
the heat dissipation board according to claim 1; and
an electronic component mounted on an upper surface of the heat dissipation board in an area aligning with the at least one through-hole in a plan view.

9. The heat dissipation board according to claim 2, wherein
the substrate comprises molybdenum, and
the first portion, the second portion, and the third portion comprise copper.

10. The heat dissipation board according to claim 2, further comprising:
a plating layer on a surface of the substrate and on an inner surface of the at least one through-hole.

11. The heat dissipation board according to claim 2, wherein
the at least one through-hole is circular in a plan view.

12. The heat dissipation board according to claim 2, wherein
the first portion, the second portion, and the third portion each comprise the same material.

13. The heat dissipation board according to claim 2, further comprising:
a second substrate having at least one second through-hole, the second substrate being on an upper surface of the second portion or on a lower surface of the third portion, the second substrate comprising a metal material;
a fourth portion in the at least one second through-hole, the fourth portion having a higher thermal conductivity than the second substrate and comprising a metal material; and
a fifth portion having a higher thermal conductivity than the second substrate and comprising a metal material, the fifth portion being on an upper surface or a lower surface of the second substrate.

14. An electronic apparatus, comprising:
the heat dissipation board according to claim 2; and
an electronic component mounted on an upper surface of the heat dissipation board in an area aligning with the at least one through-hole in a plan view.
